(19) United States
(12) Patent Application Publication
(10) Pub. No.: US 2026/0262390 A1
(43) Pub. Date: Sep. 3, 2026

(54) DISPLAY PANEL AND PREPARATION METHOD THEREFOR, AND DISPLAY DEVICE

(71) Applicants: Hefei Visionox Technology Co., Ltd., Hefei (CN); Visionox Technology Inc., Kunshan (CN)

(72) Inventors: Wenyu ZENG, Hefei (CN); Peng QIN, Kunshan (CN)

(73) Assignees: Hefei Visionox Technology Co., Ltd., Hefei (CN); Visionox Technology Inc., Kunshan (CN)

(21) Appl. No.: 19/417,277

(22) Filed: Dec. 11, 2025

(30) Foreign Application Priority Data
Feb. 28, 2025 (CN) 202510244489.5

(51) Int. Cl. H10K 59/122; H10K 59/12

(52) U.S. Cl. CPC H10K 59/122; H10K 59/1201

(57) ABSTRACT

The present disclosure provides a display panel and a preparation method therefor, and a display device. The display panel has an active area and a non-active area surrounding the active area. The non-active area includes a transition area surrounding and adjacent to the active area. The transition area includes a positioning area. The display panel further includes a substrate, and an isolation structure, a filling structure and a plurality of light-emitting devices which are located on the substrate. The light-emitting devices are located in the active area and the transition area. The isolation structure includes a plurality of isolation openings, and is located in the active area and the transition area. The isolation openings respectively correspond to the light-emitting devices and limit the corresponding light-emitting devices. The filling structure is located in the positioning area and on a side of the isolation structure away from the substrate.

### CROSS-REFERENCE TO RELATED APPLICATIONS

The present application claims priority to the Chinese Patent Application NO. 202510244489.5, filed on February 28, 2025, and the entire contents of the aforementioned application are hereby incorporated by reference in its entirety.

### FIELD

The present disclosure relates to the field of display, and in particular to a display panel and a preparation meth·od therefor, and a display device.

### BACKGROUND

An organic light-emitting diode (OLED) is an organic thin-film electroluminescent unit, which has received great attention and has been widely used in electronic display products thanks to its advantages such as simple preparation process, low cost, low power consumption, high luminance, wide angle of view, high contrast, and enabling flexible display.

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in patents CN 118251982 A, CN 116648095 A, CN 117062489 A, CN 118742138 A, CN 118678783 A, CN 118660598 A, CN 118675450 A, CN 118824188 A, and CN 118781966 A.

However, due to the structural design limitations of current electronic display products, it is challenging to further improve the accuracy of alignment operation while increasing the pixels-per-inch, thereby making it difficult to further improve the yield of display panels.

### SUMMARY

A first aspect of the present disclosure provides a display panel having an active area and a non-active area surrounding the active area. The non-active area includes a transition area surrounding and adjacent to the active area. The transition area includes a positioning area. The display panel further includes a substrate, and an isolation structure, at least one filling structure and a plurality of light-emitting devices which are located on the substrate. The light-emitting devices are located in the active area and the transition area. The isolation structure includes a plurality of isolation openings, and is located in the active area and the transition area. The isolation openings respectively correspond to the light-emitting devices and limit the corresponding light-emitting devices. The filling structure is located in the positioning area and on a side of the isolation structure away from the substrate.

In the above embodiments, the isolation structure extends into the transition area, thereby acting as a shielding layer to prevent signal interference in the transition area. In addition, the filling structure in the positioning area can cover the isolation structure and there is a difference in reflectivity (layer difference) between the positioning area and the surrounding area, thereby improving the alignment accuracy of the display panel.

In one embodiment of the first aspect of the present disclosure, the light-emitting device includes a first electrode, a light-emitting functional layer, and a second electrode sequentially stacked on the substrate, the light-emitting functional layer and the second electrode being located in the isolation opening.

In one embodiment of the first aspect of the present disclosure, the display panel may further include a first encapsulation layer, where the first encapsulation layer is located on the side of the isolation structure away from the substrate, and the first encapsulation layer includes a plurality of encapsulation units respectively corresponding to the isolation openings to cover the light-emitting devices defined by the isolation openings.

In one embodiment of the first aspect of the present disclosure, the filling structure includes at least two filling layers stacked on the isolation structure, the filling layer being in the same layer and made of the same material as the light-emitting functional layers, the second electrodes, and the first encapsulation layer. In this way, the filling structure may be prepared simultaneously during the preparation of the light-emitting device and the first encapsulation layer, thereby simplifying the preparation process of the display panel.

In one embodiment of the first aspect of the present disclosure, the light-emitting devices are classified as a first type of light-emitting devices, a second type of light-emitting devices and a third type of light-emitting devices that emit different colors of light, all the light-emitting devices corresponding to the isolation openings in the positioning area being the first type of light-emitting devices, and the at least two filling layers include a first filling layer and a second filling layer stacked on the isolation structure. In the positioning area, the first filling layer is in the same layer and made of the same material as the light-emitting functional layers and the second electrodes of the first type of light-emitting devices, and the encapsulation units corresponding to the first type of light-emitting devices, and the second filling layer is in the same layer and made of the same material as the light-emitting functional layers and the second electrodes of the second type of light-emitting devices, and the encapsulation units corresponding to the second type of light-emitting devices. In this way, the coverage of the filling structure in the positioning area can be increased, and the thickness of the filling structure on the isolation structure can be increased to increase the height of the filling structure, and the layer differentiation between the positioning area and the surrounding area is increased to further improve the alignment accuracy of the display panel.

In one embodiment of the first aspect of the present disclosure, between at least two of the light-emitting devices in the positioning area, an orthographic projection of the isolation structure on the substrate is located within an orthographic projection of one of the first filling layer and the second filling layer on the substrate, and coincides with an orthographic projection of the other of the first filling layer and the second filling layer on the substrate. The first filling layer is located between the second filling layer and the isolation structure. In the positioning area, an orthographic projection on the substrate of the isolation opening that is not adjacent to the active area is located within the orthographic projection of the second filling layer on the substrate.

In one embodiment of the first aspect of the present disclosure, the at least two filling layers further include a third filling layer, the first filling layer, the second filling layer and the third filling layer being stacked on the isolation structure. The third filling layer is in the same layer and made of the same material as the light-emitting functional layers and the second electrodes of the third type of light-emitting devices, and the encapsulation units corresponding to the third type of light-emitting devices. In this way, the coverage of the filling structure in the positioning area can be increased, and the thickness of the filling structure on the isolation structure can be further increased to further increase the height of the filling structure, and the layer differentiation between the positioning area and the surrounding area is further increased to further improve the alignment accuracy of the display panel.

In one embodiment of the first aspect of the present disclosure, between at least two of the light-emitting devices in the positioning area, an orthographic projection of the isolation structure on the substrate is located within an orthographic projection of at least one of the first filling layer, the second filling layer and the third filling layer on the substrate, and coincides with an orthographic projection of at least one of the first filling layer, the second filling layer and the third filling layer on the substrate, and the first filling layer, the second filling layer and the third filling layer are successively stacked in a direction away from the substrate. In the positioning area, an orthographic projection on the substrate of the isolation opening that is not adjacent to the active area is located within the orthographic projections of the second filling layer and the third filling layer on the substrate.

In one embodiment of the first aspect of the present disclosure, the positioning area surrounds the active area, and an orthographic projection of the transition area on the substrate coincides with an orthographic projection of the positioning area on the substrate.

In another embodiment of the first aspect of the present disclosure, the positioning area is located on at least one side of the active area, and the orthographic projection of the positioning area on the substrate is located within the orthographic projection of the transition area on the substrate.

In one embodiment of the first aspect of the present disclosure, the display panel may further include a pixel defining layer, where the pixel defining layer is located between the isolation structure and the substrate and includes a plurality of pixel openings. At least part of the isolation openings respectively correspond to the pixel openings, and the pixel opening and the isolation opening corresponding to each other are in communicate with each other.

In one embodiment, an orthographic projection on the substrate of an end of the isolation structure facing the substrate is located within an orthographic projection of the pixel defining layer on the substrate.

In one embodiment, the pixel defining layer is an inorganic film layer. When the light-emitting devices are prepared using the isolation structure, the pixel defining layer does not need to have a large thickness to accommodate and partition part of the film layers of the light-emitting devices, and the pixel defining layer can be prepared directly using an inorganic material. In this way, the pixel defining layer can separate the isolation structure from the first electrodes, and a smaller gap is designed between the first electrodes. This reduces the gap between pixels, thereby increasing the pixels-per-inch (PPI) of the display panel. In addition, the inorganic layer has high compactness and high resistivity, thereby reducing the design thickness of the display panel. Furthermore, the thickness of the inorganic film layer is relatively small, which makes the pixel opening have a small depth, to ensure the continuity of the film layer (e.g., the second electrode) formed at the pixel opening. Furthermore, as an inorganic film layer, the pixel defining layer can have a strong bonding strength with the isolation structure, thereby reducing the risk of detachment of the isolation structure.

In one embodiment of the first aspect of the present disclosure, the pixel openings are distributed in the active area and the transition area, and the pixel openings correspond to the isolation openings on a one-to-one basis.

In one embodiment of the first aspect of the present disclosure, the pixel openings are located in the active area, the pixel openings correspond to the isolation openings on a one-to-one basis in the active area, and an orthographic projection of the isolation opening on the substrate is located within an orthographic projection of the pixel defining layer on the substrate in the transition area.

In one embodiment of the first aspect of the present disclosure, the display panel may further include a touch structure, where an orthographic projection of the positioning area on the substrate is located within an orthographic projection of the transition area on the substrate, the touch structure is located on the side of the isolation structure away from the substrate, and an orthographic projection of part of the touch structure on the substrate is located within the transition area. In this way, in the transition area, the structure composed of the isolation structure and the second electrode of the light-emitting device can shield a signal line and the touch structure in the display panel to avoid signal interference between the signal line and the touch structure.

In one embodiment of the first aspect of the present disclosure, the touch structure includes a touch electrode structure and a touch trace, an orthographic projection of the touch electrode structure on the substrate being located within the active area, and an orthographic projection of at least part of the touch trace on the substrate being located within the transition area. In this way, in the transition area, the touch trace will avoid the positioning area. Therefore, the structure composed of the isolation structure and the second electrode of the light-emitting device can shield the signal line and the touch trace of the touch structure in the display panel to avoid signal interference between the signal line and the touch trace.

In one embodiment of the first aspect of the present disclosure, the touch electrode structure includes a plurality of first touch electrodes arranged in parallel and a plurality of second touch electrodes arranged in parallel, the first touch electrode and the second touch electrode intersecting each other. The touch trace includes a first touch signal line connected to the first touch electrode, and a second touch signal line connected to the second touch electrode.

In one embodiment, the first touch electrode includes a plurality of first touch electrode blocks spaced apart from each other and a plurality of first connecting portions, the first touch electrode blocks of the first touch electrode being connected to each other via the first connecting portions, and the second touch electrode includes a plurality of second touch electrode blocks spaced apart from each other and a plurality of second connecting portions, the second touch electrode blocks of the second touch electrode being connected to each other via the second connecting portions, and the first connecting portion and the second connecting portion intersecting each other.

In one embodiment, the first touch electrode is in the same layer and made of the same material as the second touch electrode block, the second connecting portion is located at a different layer from the second touch electrode block, and the second connecting portion is a conductive bridge.

A second aspect of the present disclosure provides a preparation method for a display panel. The preparation method includes: providing a substrate, which defines an active area and a non-active area surrounding the active area, the non-active area including a transition area surrounding and adjacent to the active area, the transition area including a positioning area; forming a plurality of first electrodes on the substrate, where the first electrodes are formed in the active area and the transition area; forming an isolation structure having a plurality of isolation openings on the substrate, where the isolation structure is formed in the active area and the transition area, and the isolation openings respectively correspond to the first electrodes; and forming light-emitting functional layers, second electrodes and a filling structure on the substrate, the light-emitting functional layer and the second electrode being formed in the isolation opening, the first electrode, the light-emitting functional layer and the second electrode stacked in the isolation opening forming a light-emitting device, and the filling structure being formed in the positioning area and on a side of the isolation structure away from the substrate.

In the display panel obtained by the above preparation method, the isolation structure extends into the transition area, thereby acting as a shielding layer to prevent signal interference in the transition area. In addition, the filling structure in the positioning area can cover the isolation structure and there is a difference in reflectivity (layer difference) between the positioning area and the surrounding area, thereby improving the alignment accuracy of the display panel.

In one embodiment of the second aspect of the present disclosure, the step of forming light-emitting functional layers, second electrodes and a filling structure on the substrate may include: depositing a light-emitting functional material and an electrode material after the isolation structure is formed, to respectively form a light-emitting functional structure layer and a second electrode structure layer; depositing a first insulating material film layer to form a first encapsulation structure layer; forming a photoresist layer on the first encapsulation structure layer and patterning the photoresist layer to form a photoresist pattern, the photoresist pattern covering part of the isolation openings in the active area and covering the positioning area; etching the first encapsulation structure layer, the second electrode structure layer and the light-emitting functional structure layer based on the photoresist pattern, and removing parts of the first encapsulation structure layer, the second electrode structure layer and the light-emitting functional structure layer that are not covered by the photoresist pattern, the remaining parts of the first encapsulation structure layer, the second electrode structure layer and the light-emitting functional structure layer respectively forming encapsulation units, second electrodes and light-emitting functional layers, and the first electrode, the light-emitting functional layer and the second electrode stacked in each of the isolation openings forming a light-emitting device, where in the positioning area, parts of the first encapsulation structure layer, the second electrode structure layer and the light-emitting functional structure layer that cover the isolation structure are configured to form the filling structure; removing the rest of the photoresist pattern; and repeating the above steps to form the light-emitting functional layers, the second electrodes, and the encapsulation units at the remaining isolation openings in the active area, and using the light-emitting functional layers, the second electrodes and the first encapsulation structure layer formed repeatedly in at least part of the isolation openings in the positioning area to form the filling structure, where the light-emitting functional layers formed in different processes have different emission colors, and all the encapsulation units form a first encapsulation layer.

In one embodiment of the second aspect of the present disclosure, the preparation method may further include: depositing a pixel defining material film layer on the substrate after forming the first electrodes and before forming the isolation structure; and patterning the pixel defining material film layer after the isolation structure is formed, to form a plurality of pixel openings in the pixel defining layer, where at least part of the isolation openings respectively correspond to the pixel openings, and the pixel opening and the isolation opening corresponding to each other are in communicate with each other.

In one embodiment of the second aspect of the present disclosure, the pixel openings are distributed in the active area and the transition area, and the pixel openings correspond to the isolation openings on a one-to-one basis.

In another embodiment of the second aspect of the present disclosure, the pixel openings are located in the active area, the pixel openings correspond to the isolation openings on a one-to-one basis in the active area, and an orthographic projection of the isolation opening on the substrate is located within an orthographic projection of the pixel defining layer on the substrate in the transition area.

A third aspect of the present disclosure provides a display device. The display device includes the display panel as described in the first aspect, or the display panel obtained by the preparation method as described in the second aspect.

In one embodiment of the third aspect of the present disclosure, the display device may further include a cover plate located on the side of the isolation structure away from the substrate and covering the active area and the non-active area of the display panel.

### BRIEF DESCRIPTION OF THE DRAWINGS

FIG. 1 is a planar structural schematic diagram of a display panel according to an embodiment of the present disclosure.

FIG. 2 is an enlarged view of part S1 of the display panel shown in FIG. 1 with one design.

FIG. 3 is a cross-sectional view of the display panel shown in FIG. 2 along line M1-N1.

FIG. 4 is a cross-sectional view of the display panel shown in FIG. 2 along line M2-N2.

FIG. 5 is a cross-sectional view of the display panel shown in FIG. 2 along line M3-N3.

FIG. 6 is a cross-sectional view of the display panel shown in FIG. 2 along line M3-N3 with another design.

FIG. 7 is an enlarged view of part S1 of the display panel shown in FIG. 1 with another design.

FIG. 8A is a cross-sectional view of the display panel shown in FIG. 2 along line M2-N2 with another design.

FIG. 8B is a cross-sectional view of the display panel shown in FIG. 2 along line M3-N3 with another design.

FIG. 9 is a cross-sectional view of the display panel shown in FIG. 2 along line M1-N1 with another design.

FIG. 10 is a cross-sectional view of the display panel shown in FIG. 2 along line M1-N1 with another design.

FIG. 11 is a cross-sectional view of the display panel shown in FIG. 2 along line M1-N1 with another design.

FIG. 12 is a planar structural schematic diagram of an active area of the display panel corresponding to FIG. 11.

FIG. 13A is a partial enlarged view of the display panel shown in FIG. 12.

FIG. 13B is a cross-sectional view of the structure shown in FIG. 13A taken along line M4-N4.

FIG. 13C is a cross-sectional view of the structure shown in FIG. 13A taken along line M5-N5.

FIG. 14 is a flowchart of a preparation method for a display panel according to an embodiment of the present disclosure.

FIG. 15 is a flowchart of another preparation method for a display panel according to an embodiment of the present disclosure.

FIGS. 16A to 16I are process diagrams of a preparation method for forming the display panel shown in FIG. 4 according to an embodiment of the present disclosure.

FIG. 17 is a partial structural schematic diagram of a display device according to an embodiment of the present disclosure.

### LIST OF REFERENCE SIGNS

10 - Display panel; 11 - Active area; 12 - Non-active area; 13 - Transition area; 14 - Positioning area; 15 - Bonding area;

100 - Substrate; 200 - Light-emitting device; 210 - First electrode; 220 - Light-emitting functional layer; 221 - First functional layer; 222 - Light-emitting layer; 223 - Second functional layer; 230 - Second electrode;

200a - Filling structure; 210a - First filling layer; 220a - Second filling layer; 230a - Third filling layer;

300 - Isolation structure; 301 - Isolation opening; 310 - Support portion; 320 - Crown portion; 330 - Bottom portion; 400 - Pixel defining layer; 401 - Pixel opening;

500 - encapsulation structure; 510 - First encapsulation layer; 511 - Encapsulation unit; 520 - Second encapsulation layer; 530 - Third encapsulation layer;

600 - Touch structure; 610 - First touch electrode; 611 - First touch electrode block; 612 - First connecting portion; 620 - Second touch electrode; 621 - Second touch electrode block; 622 - Second connecting portion; 630 - Touch trace; 631 - First touch signal line; 632 - Second touch signal line;

700 - Photoresist pattern; 800 - Cover plate.

### DETAILED DESCRIPTION OF THE EMBODIMENTS

The embodiments of the specification will be clearly and completely described below in conjunction with the accompanying drawings in the embodiments of the specification. Apparently, the embodiments described are merely some rather than all of the embodiments of the specification.

In a display product, some functional film layers in light-emitting devices may be formed by means of evaporation. However, since there are various functional film layers in each light-emitting device and some functional film layers (e.g., light-emitting layers) in the light-emitting devices that emit different types of light are made of different materials, it is necessary to perform multiple alignments during evaporation of these functional film layers via masks (e.g., fine masks). In order to solve the problem of position offset caused by the alignment accuracy error, enough space (safety margin related to the alignment error) needs to be reserved between the different light-emitting devices to ensure that the location of the actual light-emitting region of each light-emitting device may have a certain overlap rate with the design location (design area). This actually compresses the design area of the light-emitting region of the light-emitting device, not only limiting the light-emitting area of the light-emitting device, but also preventing a further increase of the arrangement density of the light-emitting devices, and it is difficult to further improve the pixels-per-inch (PPI) of a display panel.

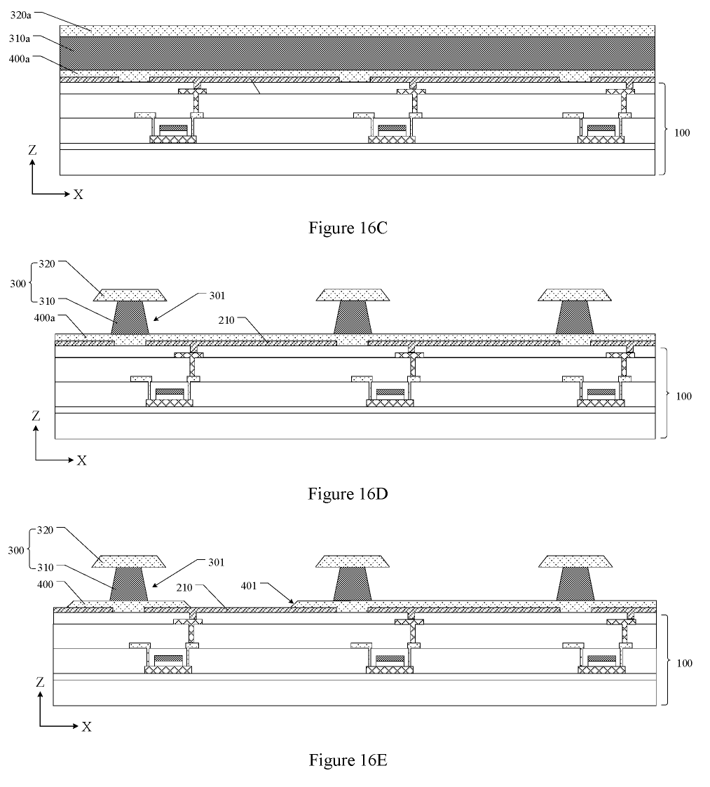

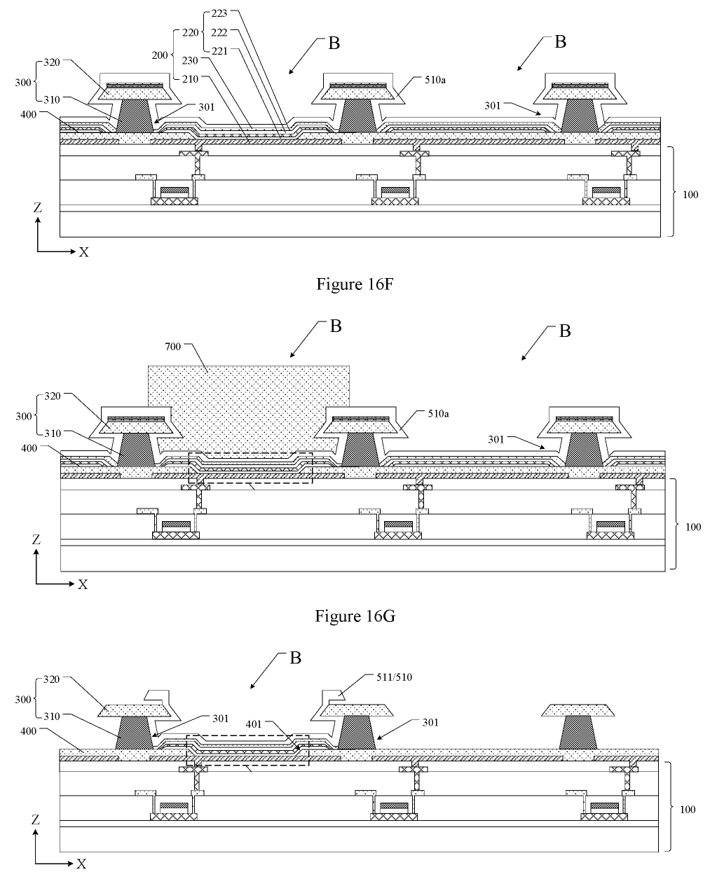

In the present disclosure, the functional film layers of adjacent light-emitting devices are separated by providing an isolation structure (an isolation structure as described below and a second isolation structure) at a gap between the light-emitting devices, and in the evaporation process for the functional film layers, it is only necessary to carry out the whole-surface evaporation on the display panel without the need to separately prepare the functional film layers of each light-emitting device by means of a mask. In this process, there is no need to take into account the problem of alignment accuracy during evaporation, and thus the gap between the light-emitting devices can be designed to have a small size to increase the PPI (for the principle, reference may be made to the relevant description of the following embodiments related to FIGS. 16A to 16I).

In some scenarios, circuits are arranged in a non-active area of the display panel near an active area, and signal interference may easily occur between these circuits when driven, resulting in poor functionality of the display panel. In view of this, the isolation structure may extend to the non-active area to act as a shielding layer to eliminate the problem of signal interference between the circuits.

The applicant has found that if the isolation structure extends to a non-active area, the reflectivity of the display panel as a whole is made relatively uniform, and when the display panel is aligned with another structure such as a cover plate, it is difficult to determine an edge position of the display panel, resulting in poor alignment accuracy, which severely limits the improvement in the yield of display products.

The embodiments of the present disclosure provide a display panel and a preparation method therefor, and a display device, to solve at least the above problems. The display panel has an active area and a non-active area surrounding the active area. The non-active area includes a transition area surrounding and adjacent to the active area. The transition area includes a positioning area. The display panel further includes a substrate, and an isolation structure, a filling structure and a plurality of light-emitting devices which are located on the substrate. The light-emitting devices are located in the active area and the transition area. The isolation structure includes a plurality of isolation openings, and is located in the active area and the transition area. The isolation openings respectively correspond to the light-emitting devices and limit the corresponding light- emitting devices. The filling structure is located in the positioning area and on a side of the isolation structure away from the substrate. In the display panel, the isolation structure extends into the transition area, thereby acting as a shielding layer to prevent signal interference in the transition area. In addition, the filling structure in the positioning area can cover the isolation structure and there is a difference in reflectivity (layer difference) between the positioning area and the surrounding area, thereby improving the alignment accuracy of the display panel.

Structures of a display panel and a display device according to at least one embodiment of the present disclosure will be described below with reference to the drawings. In addition, in these drawings, a spatial rectangular coordinate system is established with the substrate of the display panel as a reference to more intuitively present the positional relationship of the relevant structures in the display panel. In the spatial rectangular coordinate system, an X-axis and a Y-axis are parallel to the plane where the substrate is located, and a Z-axis is perpendicular to the plane where the substrate is located.

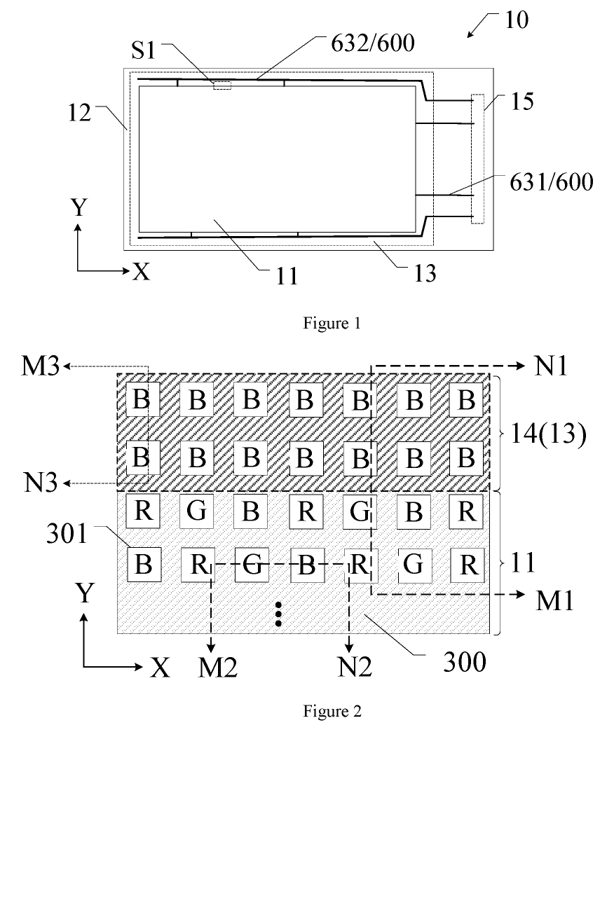

As shown in FIGS. 1 to 5, the display panel 10 includes an active area 11 and a non-active area 12 surrounding the active area 11. The non-active area 12 includes a transition area 13 adjacent to the active area 11, and the transition area 13 including a positioning area 14. There may be sub-pixels (which may be referred to as subpixels) arranged in the active area 11, such as sub-pixels R, G and B, and physical structures of the sub-pixels may be light-emitting devices in the embodiments below, and adjacent sub-pixels emitting different colors of light form a pixel (which may be referred to as a pixel unit, a large pixel, etc.). The density of the pixels arranged in the active area 11 represents the pixels-per-inch (PPI).

The physical structure of the display panel 10 includes a substrate 100, and an isolation structure 300, a filling structure 200a and a plurality of light-emitting devices 200 located on the substrate 100. The light-emitting devices 200 are physical light-emitting structures of the sub-pixels R, G and B. The light-emitting device 200 is located in the active area 11 and the transition area 13. The isolation structure 300 includes a plurality of isolation openings 301, and the isolation structure 300 is located in the active area 11 and the transition area 13. The isolation openings 301 respectively correspond to the light-emitting devices 200 and limit the corresponding light-emitting devices 200. The filling structure 200a is located in the positioning area 14 and on a side of the isolation structure 300 away from the substrate 100.

In the positioning area 14, the filling structure 200a covers the isolation structure 300, and part of the filling structure 200a that is located over the isolation structure 300 has a higher height, and there may be a difference in reflectivity (layer difference) between the positioning area 14 and the surrounding area (layer difference). When capturing the depth of layers (e.g., layer structures of the same depth) for alignment, the reflectivity of the positioning area 14 differs from that of other surrounding areas, whereby the alignment accuracy of the display panel can be improved.

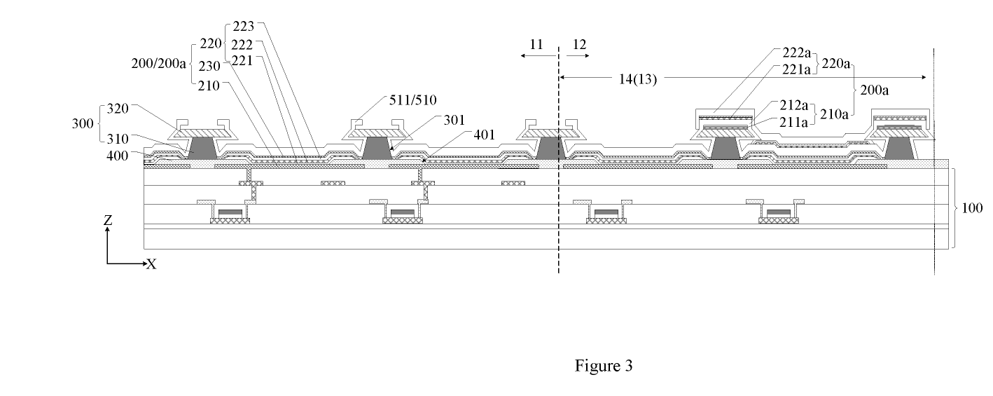

In at least one embodiment of the present disclosure, as shown in FIGS. 3 to 5, the light-emitting device 200 includes a first electrode 210, a light-emitting functional layer 220, and a second electrode 230 sequentially stacked on the substrate 100. The light-emitting functional layer 220 and the second electrode 230 are located in the isolation opening 301. In this way, the light-emitting devices 200 are distributed in both the active area 11 and the transition area 13. In other words, the preparation process of the light-emitting devices 200 is extended to the transition area 13, and during the preparation process of the light-emitting devices 200, the isolation structure 300 and the structure of the light-emitting devices 200 enable shielding of the transition area 13 to reduce the risk of signal interference in the display panel.

In at least one embodiment of the present disclosure, as shown in FIGS. 3 to 5, the light-emitting functional layer 220 may further include a light-emitting layer 222 and a second functional layer 223. A first functional layer 221, the light-emitting layer 222 and the second functional layer 223 are sequentially stacked on the first electrode 210. The first functional layer 221 may include a hole injection layer, a hole transport layer, an electron blocking layer, etc. The second functional layer 223 may include an electron injection layer, an electron transport layer, a hole blocking layer, etc. It should be noted that one or more light-emitting layers 222 may be provided in the light-emitting device 200, and in the case of a plurality of light-emitting layers are provided, the light-emitting device 200 may have higher light extraction efficiency.

For example, in at least one embodiment of the present disclosure, the first electrode 210 may be provided as an anode and the second electrode 230 may be provided as a cathode.

In at least one embodiment of the present disclosure, as shown in FIGS. 3 to 5, the substrate 100 may include a base substrate and a drive circuit layer located on the base substrate. The drive circuit layer includes a plurality of pixel driving circuits in the active area, and a display functional layer is located on the drive circuit layer. For example, each pixel driving circuit may include a plurality of thin film transistors (TFTs), capacitors, etc., which are, for example, formed in a variety of forms such as 2T1C (i.e., two thin film transistors (TFTs) and one capacitor (C)), 3T1C, or 7T1C. The pixel driving circuit is connected to the light-emitting device 200 to control an on-ff state and the luminous brightness of the light-emitting device 200.

It should be noted that the light-emitting device 200 in the transition area 13 may not be required to participate in light emission, and therefore, in the transition area 13, the pixel driving circuit may not be connected to the first electrode 210 of the light-emitting device 200.

For example, in an embodiment of the present disclosure, the layers captured during alignment may be the first electrode 210, the isolation structure 300 (a surface thereof facing away from the substrate 100), the filling structure 200a (e.g., a film layer thereof in the same layer as the second electrode 230), etc.

In at least one embodiment of the present disclosure, as shown in FIGS. 3 to 5, the display panel may further include a first encapsulation layer 510. The first encapsulation layer 510 is located on the side of the isolation structure 300 away from the substrate 100, and the first encapsulation layer 510 includes a plurality of encapsulation units 511. The encapsulation units 511 respectively correspond to the isolation openings 301 to cover the light-emitting devices 200 defined by the isolation openings 301. In the process of fabricating the light-emitting devices 200 in batches on the basis of the isolation structure 300, the encapsulation units 511 are synchronously formed along with the corresponding light-emitting devices 200. After each batch of the light-emitting devices 200 is prepared, the encapsulation units 511 can provide encapsulation protection for the prepared light- emitting devices 200 during the preparation process of the next batch of the light-emitting devices 200, thereby ensuring the luminous effect of the light-emitting devices 200.

In one embodiment of the first aspect of the present disclosure, the light-emitting devices 200 are classified as a plurality of types of light-emitting devices 200, such as light-emitting devices R, G, B, that emit different colors of light. The encapsulation units 511 respectively corresponding to adjacent light-emitting devices 200 emitting different colors of light are spaced apart from each other. It should be noted that the light-emitting devices 200 emitting different colors of light are separately prepared, but the film layer (the evaporated film layer such as the light-emitting functional layer) in each light-emitting device 200 is evaporated on the entire display panel during evaporation. For example, the light-emitting devices 200 are classified as light-emitting devices that emit red light (R), green light (G), and blue light (B), respectively. Taking the sequential preparation of the light-emitting devices R, G, and B as an example, when the light-emitting devices R are prepared, a light-emitting device R is formed in each of the isolation openings 301, and first encapsulation layers 510 are prepared on the display panel to cover the light-emitting devices R. Then, the first encapsulation layers 510, the second electrodes and the light-emitting functional layers in part of the isolation openings 301 (for forming the light-emitting devices G and B in a final product) are removed. In this process, the first encapsulation layers 510 serve to protect the light-emitting devices R in the other isolation openings 301 (for forming the light-emitting devices R in the final product). Based on this way, the light-emitting devices G and B are sequentially prepared, thereby finally forming the first encapsulation layers 510 as shown in FIGS. 3 to 5. That is, the first encapsulation layers 510 on the entire display panel are prepared by a plurality of preparation processes, and the first encapsulation layers 510 also form a plurality of encapsulation units 511 spaced apart from each other.

It should be noted that, in the embodiments of the present disclosure, the preparation sequence for the three types of light-emitting devices R, G, and B is not limited, and can be designed according to the requirements of the actual process. For example, the preparation process may also be carried out based on the order of light-emitting devices B, G, and R.

In an embodiment of the present disclosure, the filling structure 200a may be prepared simultaneously during the preparation of the light-emitting device 200 and the first encapsulation layer 510, thereby simplifying the preparation process of the display panel. For example, as shown in FIGS. 3 to 5, the filling structure 200a includes at least two filling layers such as 210a and 220a stacked on the isolation structure 300. The filling layer is in the same layer and made of the same material as the light-emitting functional layers 220, the second electrodes 230 and the first encapsulation layer 510.

In at least one embodiment of the present disclosure, as shown in FIGS. 1 to 5, the light-emitting devices 200 are classified as a first type of light-emitting devices (e.g., light-emitting devices 200 corresponding to sub-pixels B), a second type of light-emitting devices (e.g., light-emitting devices 200 corresponding to sub-pixels G) and a third type of light-emitting devices (e.g., light-emitting devices 200 corresponding to sub-pixels R) that emit different colors of light, the light-emitting devices 200 corresponding to the isolation openings 301 in the positioning area 14 are all light-emitting devices of the first type (e.g., the light-emitting devices 200 corresponding to the sub-pixels B), and the filling structure 200a includes a first filling layer 210a and a second filling layer 220a stacked on the isolation structure 300. In the positioning area 14, the first filling layer 210a is in the same layer and made of the same material as the light-emitting functional layers 220 and the second electrodes 230 of the first type of light-emitting devices, and the encapsulation units 511 corresponding to the first type of light-emitting devices, and the second filling layer 220a is in the same layer and made of the same material as the light-emitting functional layers 220 and the second electrodes 230 of the second type of light-emitting devices, and the encapsulation units 511 corresponding to the second type of light-emitting devices. In this way, the coverage of the filling structure 200a in the positioning area 14 can be increased, and the thickness of the filling structure 200a on the isolation structure 300 can be increased to increase the height of the filling structure 200a, and the layer differentiation between the positioning area 14 and the surrounding area is increased to further improve the alignment accuracy of the display panel.

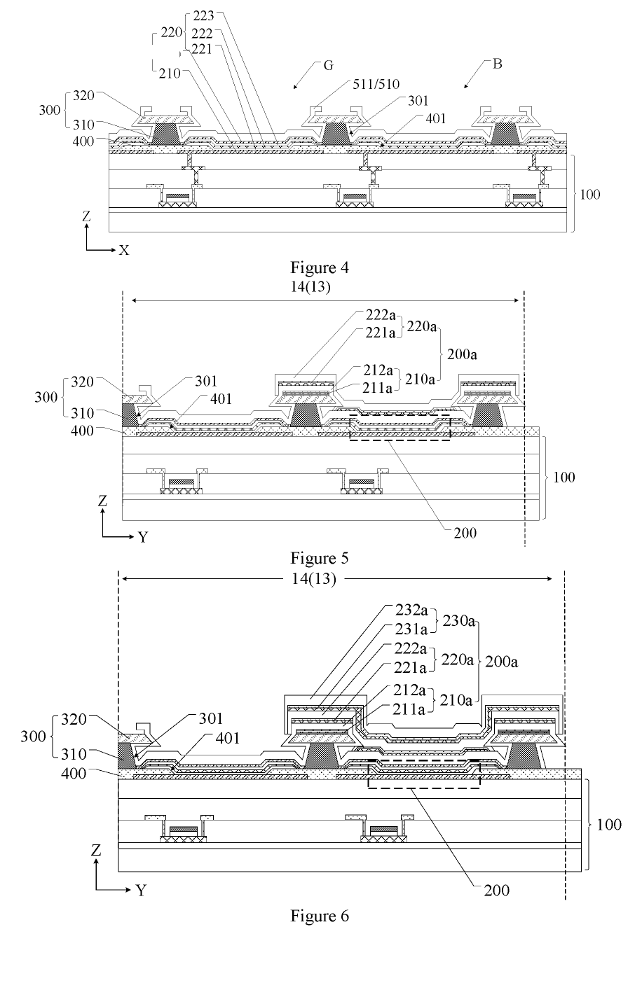

For example, as shown in FIG. 5, the first filling layer 210a includes a first film layer 211a and a second film layer 212a, and the second filling layer 220a includes a third film layer 221a and a fourth film layer 222a. The first film layer 211a is in the same layer and made of the same material as the light-emitting functional layers 220 and the second electrodes 230 of the first type of light-emitting devices, the second film layer 212a is in the same layer and made of the same material as the encapsulation units 511 corresponding to the first type of light-emitting devices, the third film layer 221a is in the same layer and made of the same material as the light-emitting functional layers 220 and the second electrodes 230 of the second type of light-emitting devices, and the fourth film layer 222a is in the same layer and made of the same material as the encapsulation units 511 corresponding to the second type of light-emitting devices.

In at least one embodiment of the present disclosure, as shown in FIG. 5, between at least two of the first type of light-emitting devices, an orthographic projection of the isolation structure 300 on the substrate 100 is located within an orthographic projection of one of the first filling layer 210a and the second filling layer 220a on the substrate 100, and coincides with an orthographic projection of the other of the first filling layer 210a and the second filling layer 220a on the substrate 100. The first filling layer 210a is located between the second filling layer 220a and the isolation structure 300. In the positioning area 14, an orthographic projection on the substrate 100 of the isolation opening 301 that is not adjacent to the active area 11 is located within the orthographic projection of the second filling layer 220a on the substrate 100.

For example, in the preparation process of the display panel as described in FIG. 5, the first type of light-emitting devices and the corresponding encapsulation units 511 may be prepared first, and the first filling layer 210a is formed in this process; and the second type of light-emitting devices are then prepared, and during the preparation of the second type of light-emitting devices, part of the film layer located in the positioning area is retained to form the second filling layer 220a.

In at least one embodiment of the present disclosure, as shown in FIG. 6, the filling structure 200a further includes a third filling layer 230a. The first filling layer 210a, the second filling layer 220a and the third filling layer 230a are stacked on the isolation structure 300, and the third filling layer 230a is in the same layer and made of the same material as the light-emitting functional layers 220 and the second electrodes 230 of the third type of light-emitting devices, and the encapsulation units 511 corresponding to the third type of light-emitting devices. In this way, the coverage of the filling structure 200a in the positioning area 14 can be increased, and the thickness of the filling structure 200a on the isolation structure 300 can be further increased to further increase the height of the filling structure 200a, and the layer differentiation between the positioning area 14 and the surrounding area is further increased to further improve the alignment accuracy of the display panel.

For example, as shown in FIG. 6, the first filling layer 210a includes a first film layer 211a and a second film layer 212a, the second filling layer 220a includes a third film layer 221a and a fourth film layer 222a, and the third filling layer 230a includes a fifth film layer 231a and a sixth film layer 232a. The first film layer 211a is in the same layer and made of the same material as the light-emitting functional layers 220 and the second electrodes 230 of the first type of light-emitting devices, the second film layer 212a is in the same layer and made of the same material as the encapsulation units 511 corresponding to the first type of light-emitting devices, the third film layer 221a is in the same layer and made of the same material as the light-emitting functional layers 220 and the second electrodes 230 of the second type of light-emitting devices, the fourth film layer 222a is in the same layer and made of the same material as the encapsulation units 511 corresponding to the second type of light-emitting devices, the fifth film layer 231a is in the same layer and made of the same material as the light-emitting functional layers 220 and the second electrodes 230 of the third type of light-emitting devices, and the sixth film layer 232a is in the same layer and made of the same material as the encapsulation units 511 corresponding to the third type of light-emitting devices.

In at least one embodiment of the present disclosure, as shown in FIG. 6, between at least two of the first type of light-emitting devices, an orthographic projection of the isolation structure 300 on the substrate 100 is located within an orthographic projection of at least one of the first filling layer 210a, the second filling layer 220a and the third filling layer 230a on the substrate 100, and coincides with an orthographic projection of at least one of the first filling layer 210a, the second filling layer 220a and the third filling layer 230a on the substrate 100, and the first filling layer 210a, the second filling layer 220a and the third filling layer 230a are successively stacked in a direction away from the substrate 100. In the positioning area 14, an orthographic projection on the substrate 100 of the isolation opening 301 that is not adjacent to the active area 11 is located within the orthographic projections of the second filling layer 220a and the third filling layer 230a on the substrate 100.

For example, in the preparation process of the display panel as described in FIG. 6, the first type of light-emitting devices and the corresponding encapsulation units 511 may be prepared first, and the first filling layer 210a is formed in this process. The second type of light-emitting devices and the third type of light-emitting devices are then sequentially prepared, and during the preparation of the second type of light-emitting devices and the third type of light-emitting devices, part of the film layer located in the positioning area is retained to form the second filling layer 220a and the third filling layer 230a.

In some embodiments of the present disclosure, as shown in FIGS. 1 and 2, the positioning area 14 surrounds the active area 11, and an orthographic projection of the transition area 13 on the substrate 100 coincides with an orthographic projection of the positioning area 14 on the substrate 100, that is, the positioning area 14 is equivalent to the transition area 13.

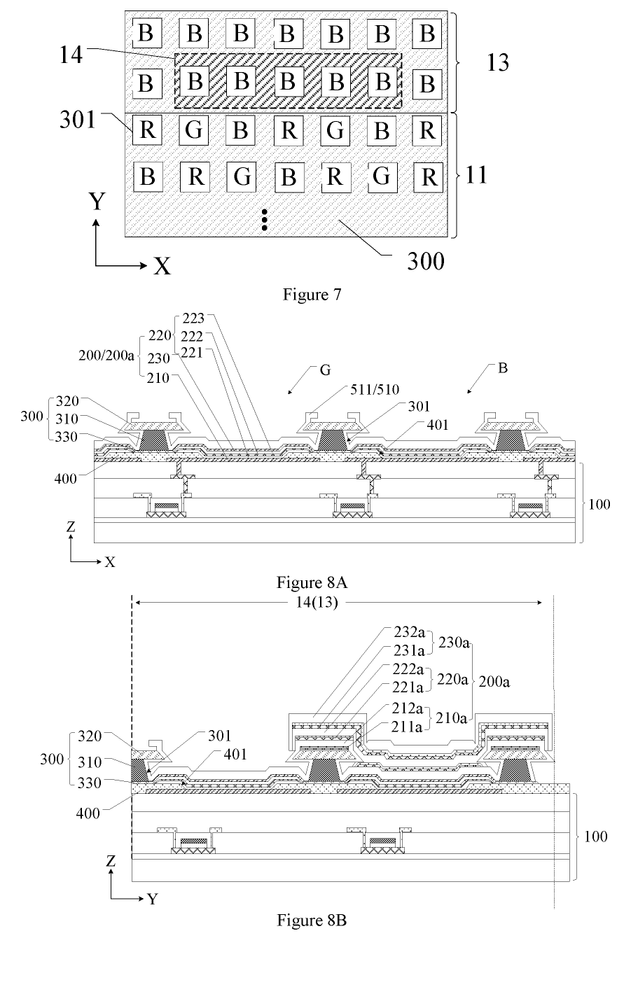

In some other embodiments of the present disclosure, as shown in FIGS. 1 and 7, the positioning area 14 is located on at least one side of the active area 11, and the orthographic projection of the positioning area 14 on the substrate 100 is located within the orthographic projection of the transition area 13 on the substrate 100, that is, part of the transition area 13 is configured as the positioning area 14, and the preparation process of the rest of the transition area 13 may be the same as the preparation process of the active area 11 in the process of preparing the light-emitting device 200 based on the isolation structure 300.

In at least one embodiment of the present disclosure, referring again to FIGS. 3 to 5, the isolation structure 300 includes a support portion 310 and a crown portion 320. The support portion 310 is located between the crown portion 320 and the substrate 100. An orthographic projection on the substrate 100 of an end of the support portion 310 facing the crown portion 320 is located within an orthographic projection of the crown portion 320 on the substrate 100. In this way, during the preparation of the light-emitting devices 200, the isolation effect of the isolation structure 300 on the light-emitting functional layers 220 can be enhanced, thereby reducing the risk of current crosstalk between different light-emitting devices 200.

For the configuration of the isolation structure 300, reference can be made to the contents in patents CN 118251982 A, 202410864269.8, PCT/CN 2024/098407, PCT/CN 2024/102783, PCT/CN 2024/098217, PCT/CN 2024/100935, PCT/CN 2024/102785, PCT/CN 2024/099419, PCT/CN 2024/099072, and CN 116685174 A. The structure of the display panel of the present disclosure will be described below with respect to several configurations of the isolation structure 300.

In at least one embodiment of the present disclosure, as shown in FIGS. 3 to 5, the support portion 310 is of a conductive structure, and the second electrode 230 is connected to a side surface of the support portion 310. The support portion 310 can be used for assisting in connecting the second electrode 230. Since the support portion 310 is located at a gap between the light-emitting devices 200, the support portion can be designed with a greater thickness (thicker than the second electrode 230) and can be prepared using a material with high electrical conductivity. Therefore, when connected to the second electrode 230, the support portion can alleviate the problem of voltage drop across the second electrode 230 when the light-emitting devices 200 are driven.

In at least one embodiment of the present disclosure, as shown in FIGS. 3 to 5, the orthographic projection on the substrate 100 of the end of the support portion 310 facing the crown portion 320 is located within the orthographic projection on the substrate 100 of an end of the support portion 310 facing the substrate 100. In this way, the support portion 310 generally presents a shape that is wider at the bottom and narrower at the top, thereby forming a relatively inclined side surface. This facilitates the deposition of an edge portion of the second electrode 230 on the side surface of the support portion 310 to increase the thickness of the portion of the second electrode 230 in contact with the support portion 310, thereby reducing the impedance at the connection between the support portion 310 and the second electrode 230.

In at least one embodiment of the present disclosure, as shown in FIGS. 3 to 5, an orthographic projection of the support portion 310 on the substrate 100 is located within the orthographic projection of the crown portion 320 on the substrate 100, and an edge of the light-emitting functional layer 220 is spaced apart from the support portion 310. In this way, the isolation structure 300 generally presents a shape that is wider at the top and narrower at the bottom. Therefore, during the evaporation of part of film layers of the light-emitting device 200 (e.g., the light-emitting functional layer 220 and the second electrode 230 mentioned in the above embodiments), by controlling an evaporation angle for each film layer, and under the blocking effect of the isolation structure 300, it is possible to ensure that an edge of a portion of the film layer (e.g., the second electrode 230 above) can be connected to the conductive structure of the isolation structure 300 (e.g., the support portion 310), while preventing another portion of the film layer (e.g., the light-emitting functional layer or a portion of the film layer including a hole material, i.e., the first functional layer 221) from coming into contact with the isolation structure 300. In this way, while isolating a portion of the film layer (including electrical isolation, and the light-emitting functional layers or portions of film layers of adjacent light-emitting devices are not directly or indirectly electrically connected), it is ensured that another portion of the film layer (e.g., the above second electrode 230) can be connected to the conductive structure of the isolation structure 300.

In at least one embodiment of the present disclosure, as shown in FIGS. 8A and 8B, the isolation structure 300 may further include a bottom portion 330. The bottom portion 330 is located between the support portion 310 and the substrate 100, and the orthographic projection of the support portion 310 on the substrate 100 is located within an orthographic projection of the bottom portion 330 on the substrate 100. Compared to the support portion 310, a surface of the bottom portion 330 facing away from the substrate 100 is more conducive to the deposition of the second electrode 230, thereby further reducing the impedance at the connection between the isolation structure 300 and the second electrode 230.

In one embodiment, the orthographic projection of the bottom portion 330 on the substrate 100 is located within the orthographic projection of the crown portion 320 on the substrate 100. In this way, during the preparation of the light-emitting functional layer 220 and the second electrode 230, an evaporation angle of an evaporation apparatus can be controlled and at least part of the film layer of the light-emitting functional layer 220 is disconnected from the bottom portion 330 while ensuring that the second electrode 230 is connected to the bottom portion 330.

For example, the bottom portion 330, the support portion 310 and the crown portion 320 may be respectively made of molybdenum, aluminum and titanium. The corrosion resistances of aluminum, molybdenum and titanium increase in that order, and during etching, the film layers formed from these materials may form the isolation structure 300 as shown in FIGS. 8A and 8B.

In at least one embodiment of the present disclosure, as shown in FIGS. 8A and 8B, the display panel may further include a pixel defining layer 400. The pixel defining layer 400 is located between the isolation structure 300 and the substrate 100 and includes a plurality of pixel openings 401. At least part of the isolation openings 301 respectively correspond to the pixel openings 401, and the pixel opening 401 and the isolation opening 301 corresponding to each other are in communicate with each other. The pixel defining layer 400 is used to space the first electrode 210 apart from the isolation structure 300 to avoid short circuits.

In at least one embodiment of the present disclosure, as shown in FIGS. 8A and 8B, an orthographic projection on the substrate 100 of an end of the isolation structure 300 facing the substrate 100 is located within an orthographic projection of the pixel defining layer 400 on the substrate 100. In this way, the isolation structure 300 completely falls on the pixel defining layer 400 to improve the flatness of each film layer of the isolation structure 300.

In at least one embodiment of the present disclosure, the pixel defining layer 400 may be an inorganic film layer. When the light-emitting devices 200 are prepared using the isolation structure 300, the pixel defining layer 400 does not need to have a large thickness to accommodate and partition part of the film layers of the light-emitting devices 200, and the pixel defining layer 400 can be prepared directly using an inorganic material. In this way, the pixel defining layer 400 can separate the isolation structure 300 from the first electrodes 210, and a smaller gap is designed between the first electrodes 210. This reduces the gap between the pixels, thereby increasing the pixels-per-inch (PPI) of the display panel. In addition, the inorganic layer has high compactness and high resistivity, thereby reducing the design thickness of the display panel. Furthermore, the thickness of the inorganic film layer is relatively small, which makes the pixel opening 401 have a small depth, to ensure the continuity of the film layer (e.g., the second electrode 230) formed at the pixel opening 401. Furthermore, as an inorganic film layer, the pixel defining layer 400 has a strong bonding strength with the isolation structure 300, thereby reducing the risk of detachment of the isolation structure 300.

In some embodiments of the present disclosure, as shown in FIGS. 8A and 8B, the pixel openings 401 are distributed in the active area 11 and the transition area 13, and the pixel openings 401 correspond to the isolation openings 301 on a one-to-one basis.

For example, as shown in FIGS. 8A and 8B, at least one of the pixel openings 401 is located in the positioning area 14 and corresponds to the first electrode in the positioning area 14.

For example, as shown in FIGS. 8A and 8B, in the position where the isolation opening 301 is provided, the pixel defining layer 400 is located between the first electrode 210 and the isolation structure 300, and an orthographic projection of the pixel opening 401 on the substrate 100 is located within an orthographic projection of the first electrode 210 on the substrate 100.

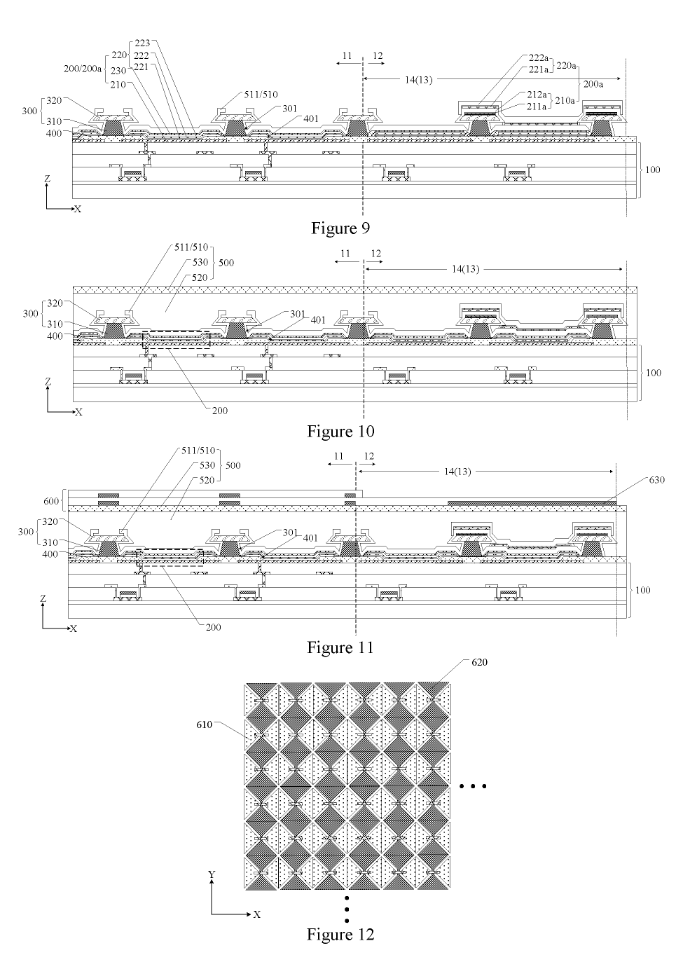

In some other embodiments of the present disclosure, as shown in FIG. 9, the pixel openings 401 are located in the active area 11. The pixel openings 401 correspond to the isolation openings 301 on a one-to-one basis in the active area 11, and the orthographic projection of the isolation opening 301 on the substrate 100 is located within the orthographic projection of the pixel defining layer 400 on the substrate 100 in the transition area 13. The light-emitting devices 200 in the transition area 13 are not used for display, and part of the pixel defining layer 400 that covers the first electrodes 210 is thus not required to form the pixel openings 401 during the preparation of the light-emitting devices 200 in the transition area 13. Therefore, in the transition area 13, the pixel defining layer 400 is a continuous film layer, thereby protecting the underlying structure such as signal lines in the process of preparing the light-emitting devices 200 (which involves multiple etching processes).

For example, as shown in FIG. 9, in the transition area 13, the orthographic projection of the first electrode 210 on the substrate 100 is located within the orthographic projection of the pixel defining layer 400 on the substrate 100. In the active area 11, the pixel defining layer 400 is located between the first electrode 210 and the isolation structure 300, and the orthographic projection of the pixel opening 401 on the substrate 100 is located within the orthographic projection of the first electrode 210 on the substrate 100.

In at least one embodiment of the present disclosure, as shown in FIG. 10, the display panel may further include a second encapsulation layer 520 and a third encapsulation layer 530 covering and stacked on the first encapsulation layer 510. The second encapsulation layer 520 is located between the first encapsulation layer 510 and the third encapsulation layer 530, and the first encapsulation layer 510, the second encapsulation layer 520 and the third encapsulation layer 530 form an encapsulation structure 500. For example, the first encapsulation layer 510 and the third encapsulation layer 530 are inorganic film layers, the second encapsulation layer 520 is an organic film layer, and the second encapsulation layer 520 can improve the flatness of the surface of the display panel, thereby facilitating the provision of other components (e.g., a touch structure described below) on the encapsulation structure 500. In addition, the second encapsulation layer 520 can have a certain flexibility to mitigate stresses in the first encapsulation layer 510 and the third encapsulation layer 530, thereby improving the reliability of the display panel and facilitating the application of the display panel in the field of flexible displays. Furthermore, the third encapsulation layer 530 has high compactness, provides a high barrier effect against water, oxygen, etc., and the third encapsulation layer 530 has higher strength, thereby facilitating the preparation of other components (e.g., touch function-related structures, optical film layers, etc.) thereon.

In at least one embodiment of the present disclosure, as shown in FIGS. 11 and 12, the display panel may further include a touch structure 600. An orthographic projection of the positioning area 14 on the substrate 100 is located within the orthographic projection of the transition area 13 on the substrate 100, the touch structure 600 is located on the side of the isolation structure 300 away from the substrate 100, and an orthographic projection of part of the touch structure 600 on the substrate 100 is located within the transition area 13. In this way, in the transition area 13, the structure composed of the isolation structure 300 and the second electrode 230 of the light-emitting device 200 can shield a signal line and the touch structure 600 in the display panel to avoid signal interference between the signal line and the touch structure.

In at least one embodiment of the present disclosure, as shown in FIGS. 11 and 12, the touch structure 600 includes a touch electrode structure (the structure shown in FIG. 12) and a touch trace 630. An orthographic projection of the touch electrode structure on the substrate 100 is located within the active area 11, and an orthographic projection of at least part of the touch trace 630 on the substrate 100 is located within the transition area 13. In this way, the structure composed of the isolation structure 300 and the second electrode 230 of the light-emitting device 200 can shield the signal line and the touch trace 630 of the touch structure 600 in the display panel to avoid signal interference between the signal line and the touch trace.

In at least one embodiment of the present disclosure, as shown in FIGS. 1, 11, 12 and 13A to 13C, the touch electrode structure includes a plurality of first touch electrodes 610 arranged in parallel and a plurality of second touch electrodes 620 arranged in parallel, the first touch electrode 610 and the second touch electrode 620 intersecting each other to form a touch unit (capacitor) having a touch detection function at the intersection, and the touch trace 630 includes a first touch signal line 631 and a second touch signal line 632. The first touch signal line 631 is connected to the first touch electrode 610, and the second touch signal line 632 is connected to the second touch electrode 620 for touch detection.

For example, the non-active area 12 of the display panel includes a bonding area 15. An overlapping connection terminal or a drive chip is provided in the bonding area 15, and the first touch signal line 631 and the second touch signal line 632 extend into the bonding area 15 for connection with the overlapping connection terminal or the drive chip.

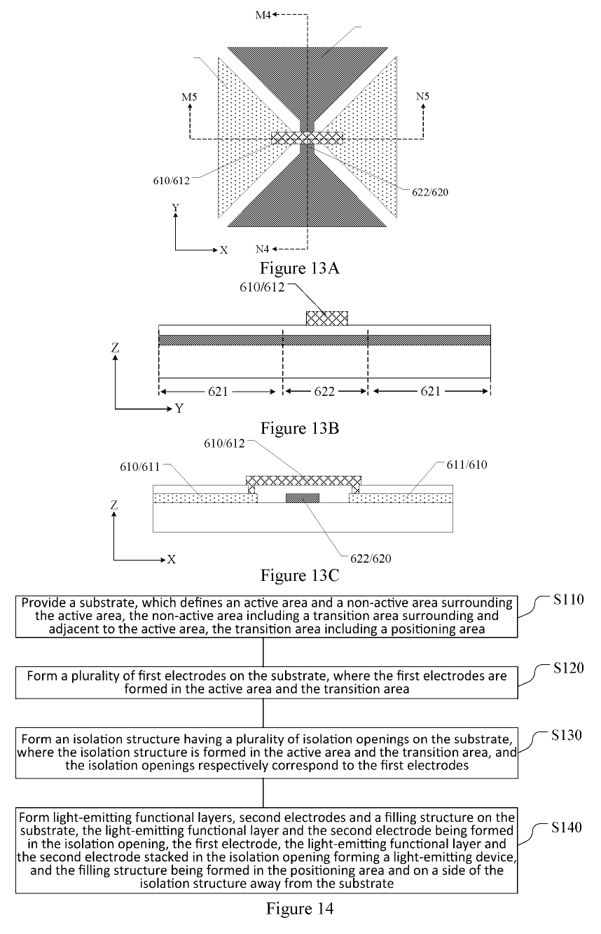

In at least one embodiment of the present disclosure, as shown in FIGS. 12 and 13A to 13C, the first touch electrode 610 includes a plurality of first touch electrode blocks 611 spaced apart from each other and a plurality of first connecting portions 612, the first touch electrode blocks 611 of the first touch electrode 610 being connected to each other via the first connecting portions 612, and the second touch electrode 620 includes a plurality of second touch electrode blocks 621 spaced apart from each other and a plurality of second connecting portions 622, the second touch electrode blocks 621 of the second touch electrode 620 being connected to each other via the second connecting portions 622, and the first connecting portion 612 and the second connecting portion 622 intersecting each other.

For example, the first touch electrode 610 is in the same layer and made of the same material as the second touch electrode block 621, the second connecting portion 622 is located at a different layer from the second touch electrode block 621, and the second connecting portion 622 is a conductive bridge.

For example, the touch trace 630 may be of a single-layer design or may be of a double-layer design. For example, in the case of the single-layer design, the touch trace 630 may be in the same layer and made of the same material as one of the first touch electrode 610 and the second connecting portion 622. In the case of the double-layer design, one layer of the touch trace 630 may be in the same layer and made of the same material as the first touch electrode 610, and the other layer thereof may be in the same layer and made of the same material as the second connecting portion 622. In this way, the touch trace 630 may be formed by double layers of conductor wires in parallel to reduce the voltage drop generated thereacross.

At least one embodiment of the present disclosure provides a preparation method for a display panel, which may include steps S110 to S140 as shown in FIG. 14, specifically as follows.

In step S110, a substrate is provided, which defines an active area and a non-active area surrounding the active area, the non-active area including a transition area surrounding and adjacent to the active area, the transition area including a positioning area.

In step S120, a plurality of first electrodes are formed on the substrate, where the first electrodes are formed in the active area and the transition area.

In step S130, an isolation structure having a plurality of isolation openings is formed on the substrate, where the isolation structure is formed in the active area and the transition area, and the isolation openings respectively correspond to the first electrodes.

In step S140, light-emitting functional layers, second electrodes and a filling structure are formed on the substrate, the light-emitting functional layer and the second electrode being formed in the isolation opening, the first electrode, the light-emitting functional layer and the second electrode stacked in the isolation opening forming a light- emitting device, and the filling structure being formed in the positioning area and on a side of the isolation structure away from the substrate.

In the display panel prepared in steps S110 to S140, the isolation structure extends into the transition area, thereby acting as a shielding layer to prevent signal interference in the transition area. In addition, the filling structure in the positioning area can cover the isolation structure and there is a difference in reflectivity (layer difference) between the positioning area and the surrounding area, thereby improving the alignment accuracy of the display panel. For the structure of the display panel obtained by the preparation method, reference may be made to the relevant descriptions of the foregoing embodiments, which will not be repeated herein.

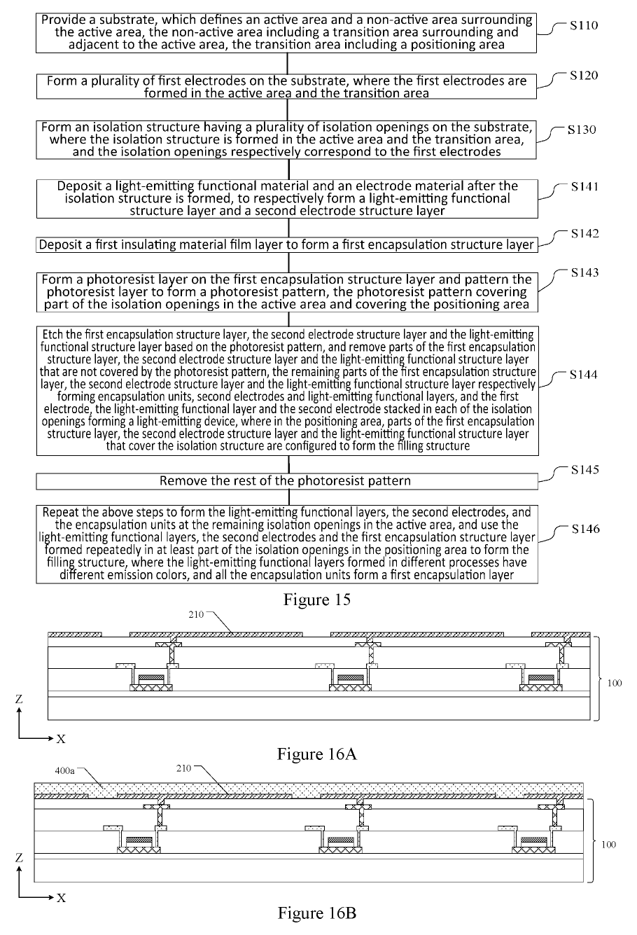

In the preparation method for a display panel according to at least one embodiment of the present disclosure, the above step S140 may include the following steps S141 to S146 as shown in FIG. 15, specifically as follows.

In step S141, after the isolation structure is formed, a light-emitting functional material and an electrode material are deposited to respectively form a light-emitting functional structure layer and a second electrode structure layer.

In step S142, a first insulating material film layer is deposited to form a first encapsulation structure layer.

In step S143, a photoresist layer is formed on the first encapsulation structure layer and the photoresist layer is patterned to form a photoresist pattern, the photoresist pattern covering part of the isolation openings in the active area and covering the positioning area.

In step S144, the first encapsulation structure layer, the second electrode structure layer and the light-emitting functional structure layer are etched based on the photoresist pattern, and parts of the first encapsulation structure layer, the second electrode structure layer and the light-emitting functional structure layer that are not covered by the photoresist pattern are removed, the remaining parts of the first encapsulation structure layer, the second electrode structure layer and the light-emitting functional structure layer respectively forming encapsulation units, second electrodes and light-emitting functional layers, and the first electrode, the light-emitting functional layer and the second electrode stacked in each of the isolation openings forming a light-emitting device, where in the positioning area, parts of the first encapsulation structure layer, the second electrode structure layer and the light-emitting functional structure layer that cover the isolation structure are configured to form the filling structure.

In step S145, the rest of the photoresist pattern is removed.

In step S146, the above steps are repeated to form the light-emitting functional layers, the second electrodes, and the encapsulation units at the remaining isolation openings in the active area, and the light-emitting functional layers, the second electrodes and the first encapsulation structure layer formed repeatedly in at least part of the isolation openings in the positioning area are used to form the filling structure, where the light-emitting functional layers formed in different processes have different emission colors, and all the encapsulation units form a first encapsulation layer.

For the structure of the display panel obtained in the above steps S141 to S146, the problems solved, corresponding effects, and possible further improvements, reference may be made to the relevant descriptions of the foregoing embodiments, which will not be repeated herein.

In at least one embodiment of the present disclosure, the preparation method may further include: depositing a pixel defining material film layer on the substrate after forming the first electrodes and before forming the isolation structure; and patterning the pixel defining material film layer after the isolation structure is formed, to form a plurality of pixel openings in the pixel defining layer, where at least part of the isolation openings respectively correspond to the pixel openings, and the pixel opening and the isolation opening corresponding to each other are in communicate with each other. For the structure of the display panel obtained by the preparation method, reference may be made to the relevant descriptions of the foregoing embodiments, which will not be repeated herein.

In the preparation method for a display panel according to some embodiments of the present disclosure, the pixel openings are distributed in the active area and the transition area, and the pixel openings correspond to the isolation openings on a one-to-one basis. For the structure of the display panel obtained by the preparation method, reference may be made to the relevant descriptions of the foregoing embodiments associated with FIGS. 2 to 5, which will not be repeated herein.

In the preparation method for a display panel according to some other embodiments of the present disclosure, the pixel openings are located in the active area, the pixel openings correspond to the isolation openings on a one-to-one basis in the active area, and an orthographic projection of the isolation opening on the substrate is located within an orthographic projection of the pixel defining layer on the substrate in the transition area. For the structure of the display panel obtained by the preparation method, reference may be made to the relevant descriptions of the foregoing embodiment associated with FIG. 9, which will not be repeated herein.

The preparation process of the display panel shown in FIGS. 3 to 5 (directly showing the structure shown in FIG. 4) will be described below with respect to FIGS. 16A to 16I, in order to show directly how the display panel is prepared and the principle of the isolation structure increasing the pixels-per-inch PPI.

As shown in FIG. 16A, a substrate 100 is provided, and first electrodes 210 arranged in an array are formed on the substrate 100.

As shown in FIG. 16B, a pixel defining material film layer 400a is deposited on the substrate 100 on which the first electrodes 210 are formed.

As shown in FIG. 16C, a first material layer 310a and a second material layer 320a are formed on the pixel defining material film layer 400a. For example, a material of the first material layer 310a may be aluminum, and a material of the second material layer 320a may be titanium.

As shown in FIG. 16D, the first material layer 310a and the second material layer 320a are subjected to a patterning process and the first material layer 310a is formed as a support portion 310, and the second material layer 320a is formed as a crown portion 320. The support portion 310 and the crown portion 320 define an isolation opening 301 and form the isolation structure 300. For the specific structure of the isolation structure 300, reference may be made to the descriptions of the foregoing embodiments, which will not be repeated herein.

In the embodiments of the present disclosure, the patterning process may be a photolithographic patterning process, which, for example, may include: coating a photoresist on a structural layer to be patterned, exposing the photoresist using a mask, developing the exposed photoresist to obtain a photoresist pattern, etching (in one embodiment, wet or dry etching) the structural layer using the photoresist pattern, and then, in one embodiment, removing the photoresist pattern. It should be noted that when the material of the structural layer (e.g., a photoresist pattern 700 described below) includes the photoresist, the structural layer may be directly exposed by means of the mask to form the desired pattern.

It should be noted that if a corrosion resistance of the second material layer 320a (e.g., titanium) is greater than a corrosion resistance of the first material layer 310a (e.g., aluminum), an etching rate of the first material layer 310a may be higher than an etching rate of the second material layer 320a. As a result, a width of the crown portion 320 may be greater than a width of the support portion 310, thereby forming the structure as shown in FIG. 16D.

As shown in FIG. 16E, the pixel defining material film layer 400a is patterned to form pixel openings 401 in positions where part of the isolation openings 301 are located, and the pixel defining material film layer 400a is formed as a pixel defining layer 400 (non-final form). In this way, during the process, the pixel defining layer 400 still exists at a portion of the isolation openings 301, to protect the underlying first electrodes 210 during subsequent etching processes.

It should be noted that in the process corresponding to FIG. 16E, it is also possible to choose to form all the pixel openings 401 corresponding to the final product in a single step, thereby simplifying the process flow for preparing the display panel.

It should be noted that in the step shown in FIG. 16E, the pixel openings 401 may be formed by a photolithographic patterning process. In this process, the isolation structure 300 can also be used to expose the photoresist, thereby accurately controlling the positions in which the pixel openings 401 are formed.

As shown in FIG. 16F, a light-emitting functional material and an electrode material are evaporated on the substrate 100 to form the light-emitting devices 200 (the first type of light-emitting devices corresponding to sub-pixels B) in all the isolation openings 301 of the isolation structure 300. No mask is used in the evaporation in this process, so the evaporated material can also be deposited on the crown portion 320. It should be noted that in a practical process, the evaporated material will be deposited at an upper surface of the crown portion 320 away from the substrate 100 and on side walls (not shown). A first encapsulation film 510a is then formed by deposition to cover the light-emitting device 200 and the isolation structure 300. The light-emitting devices 200 formed during this process all emit blue light B.

It should be noted that in a position where the isolation opening 301 is formed but no pixel opening 401 is formed, the light-emitting functional layer 220 and the first electrode 210 are spaced apart from each other, and the light-emitting functional layer 220 and the first electrode 210 of the light-emitting device 200 in this position are separated from each other and the light-emitting device does not have a light-emitting function. If the structure is retained (in the transition area), the display panel as shown in FIG. 9 can be formed.

As shown in FIG. 16G, the photoresist is formed (e.g., coated) on the substrate 100 on which the first encapsulation film 510a is formed, and then subjected to a patterning process to form a photoresist pattern 700. The photoresist pattern 700 covers a positioning area, and in an active area, the photoresist pattern 700 covers only part of the isolation openings 301 of the isolation structure 300 (the isolation openings 301 corresponding to the pixel openings 401).

As shown in FIG. 16H, the photoresist pattern 700 is used as a mask to etch a surface of the display panel, to remove parts of the first encapsulation film 510a, the electrode material and the light-emitting functional material that are not covered by the photoresist pattern 700. The rest of the first encapsulation film 510a forms encapsulation units 511 of the first encapsulation layer 410; and the remaining photoresist pattern 700 is then removed.

After the process is formed, light-emitting devices 200 (a first type of light-emitting devices) and encapsulation units 511 corresponding to the light-emitting devices 200 are formed at part of the isolation openings 301 in the active area, light-emitting devices 200 (the first type of light-emitting devices) and encapsulation units 511 corresponding to the light-emitting devices 200 are formed at all the isolation openings 301 in the positioning area, and a first filling layer 210a as shown in FIG. 5 is formed on the isolation structure 300.

As shown in FIG. 16I, the pixel defining layer 400 is patterned to form pixel openings 401 in positions corresponding to the other part of the isolation openings 301 (at which no pixel opening 401 is formed).

The above steps of FIGS. 16E to 16H are repeated to form light-emitting devices 200 that emit green light G (a second type of light-emitting devices) and light-emitting devices 200 that emit red light R (a third type of light-emitting devices) respectively in the other isolation openings 301, and to form the display panel as shown in FIG. 4. It should be noted that in the process of forming the light-emitting devices 200 that emit green light G (the second type of light-emitting devices) and the light-emitting devices 200 that emit red light R (the third type of light-emitting devices), a second filling layer 220a and a third filling layer 230a as shown in FIG. 6 are formed, respectively.

At least one embodiment of the present disclosure provides a display device, which includes the display panel mentioned in any one of the foregoing embodiments or the display panel obtained by the preparation method mentioned in any one of the foregoing embodiments.

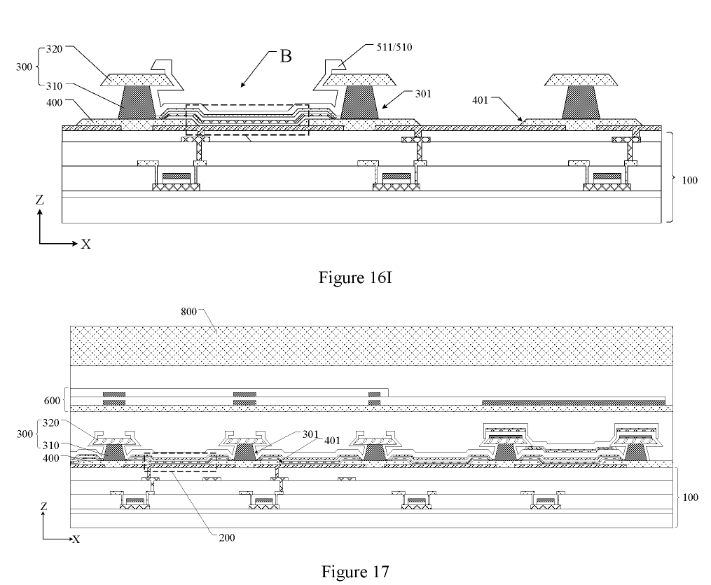

As shown in FIG. 17, a display device according to at least one embodiment of the present disclosure may further include a cover plate 800. The cover plate 800 is located on the side of the isolation structure 300 away from the substrate 100 and covers the active area and the non-active area of the display panel. During a process of aligning and bonding the display panel with the cover plate 800, an aligning and bonding apparatus can determine the position of an edge of the display panel based on the positioning area of the display panel for precise positioning.

For example, the display device may be a television, a digital camera, a cell phone, a watch, a tablet computer, a laptop computer, a navigator, or any other product or component having a display function.

It should be understood that the steps may be reordered, added, or deleted using the various forms of processes illustrated above. For example, the steps recorded in the present disclosure may be performed in parallel, sequentially, or in a different order, provided that the desired results of the embodiments of the present disclosure can be achieved, which are not limited here.

The detailed description of the above embodiments does not constitute a limitation on the scope of protection of the present disclosure. Various modifications, combinations, sub-combinations, and substitutions can be made based on design requirements and other factors. Any modifications, equivalent substitutions, or improvements made within the spirit and principle of the present disclosure should be included within the scope of protection of the present disclosure.

The above descriptions are some embodiments of the specification but not intended to limit the specification, and any modifications, equivalent replacements, etc. made within the spirit and principle of the specification should be included within the scope of protection of the specification.

1. A display panel having an active area and a non-active area surrounding the active area, the non-active area comprising a transition area surrounding and adjacent to the active area, the transition area comprising a positioning area, the display panel further comprising:
a substrate;
a plurality of light-emitting devices located in the active area and the transition area;
an isolation structure located on the substrate and comprising a plurality of isolation openings, the isolation structure being located in the active area and the transition area, and the isolation openings respectively corresponding to the light-emitting devices and limiting the corresponding light-emitting devices; and
At least one filling structure located in the positioning area and on a side of the isolation structure away from the substrate.

2. The display panel according to claim 1, wherein the light-emitting device comprises a first electrode, a light-emitting functional layer and a second electrode sequentially stacked on the substrate, the light-emitting functional layer and the second electrode being located in the isolation opening.

3. The display panel according to claim 2, further comprising a first encapsulation layer, wherein the first encapsulation layer is located on the side of the isolation structure away from the substrate, and
the first encapsulation layer comprises a plurality of encapsulation units respectively corresponding to the isolation openings to cover the light-emitting devices defined by the isolation openings.

4. The display panel according to claim 3, wherein the filling structure comprises at least two filling layers stacked on the isolation structure,
the filling layer being in the same layer and made of the same material as the light-emitting functional layers, the second electrodes, and the first encapsulation layer.

5. The display panel according to claim 4, wherein the light-emitting devices are classified as a first type of light-emitting devices, a second type of light-emitting devices and a third type of light-emitting devices that emit different colors of light, all the light-emitting devices corresponding to the isolation openings in the positioning area being the first type of light-emitting devices, and the at least two filling layers comprise a first filling layer and a second filling layer stacked on the isolation structure,
wherein in the positioning area, the first filling layer is in the same layer and made of the same material as the light-emitting functional layers and the second electrodes of the first type of light-emitting devices, and the encapsulation units corresponding to the first type of light-emitting devices, and the second filling layer is in the same layer and made of the same material as the light-emitting functional layers and the second electrodes of the second type of light-emitting devices, and the encapsulation units corresponding to the second type of light-emitting devices.

6. The display panel according to claim 5, wherein between at least two of the light-emitting devices in the positioning area, an orthographic projection of the isolation structure on the substrate is located within an orthographic projection of one of the first filling layer and the second filling layer on the substrate, and coincides with an orthographic projection of the other of the first filling layer and the second filling layer on the substrate, and the first filling layer is located between the second filling layer and the isolation structure,
wherein in the positioning area, an orthographic projection on the substrate of the isolation opening that is not adjacent to the active area is located within the orthographic projection of the second filling layer on the substrate.

7. The display panel according to claim 5, wherein the at least two filling layers further comprise a third filling layer, the first filling layer, the second filling layer and the third filling layer being stacked on the isolation structure,
wherein the third filling layer is in the same layer and made of the same material as the light-emitting functional layers and the second electrodes of the third type of light-emitting devices, and the encapsulation units corresponding to the third type of light-emitting devices.

8. The display panel according to claim 7, wherein between at least two of the light-emitting devices in the positioning area, an orthographic projection of the isolation structure on the substrate is located within an orthographic projection of at least one of the first filling layer, the second filling layer and the third filling layer on the substrate, and coincides with an orthographic projection of at least one of the first filling layer, the second filling layer and the third filling layer on the substrate, and the first filling layer, the second filling layer and the third filling layer are successively stacked in a direction away from the substrate,
wherein in the positioning area, an orthographic projection on the substrate of the isolation opening that is not adjacent to the active area is located within the orthographic projections of the second filling layer and the third filling layer on the substrate.

9. The display panel according to claim 1, wherein
the positioning area surrounds the active area, and an orthographic projection of the transition area on the substrate coincides with an orthographic projection of the positioning area on the substrate; or
the positioning area is located on at least one side of the active area, and the orthographic projection of the positioning area on the substrate is located within the orthographic projection of the transition area on the substrate.

10. The display panel according to claim 1, further comprising a pixel defining layer, wherein the pixel defining layer is located between the isolation structure and the substrate and comprises a plurality of pixel openings,
wherein at least part of the isolation openings respectively correspond to the pixel openings, and the pixel opening and the isolation opening corresponding to each other are in communicate with each other.

11. The display panel according to claim 10, wherein the pixel openings are distributed in the active area and the transition area, and the pixel openings correspond to the isolation openings on a one-to-one basis.

12. The display panel according to claim 10, wherein the pixel openings are located in the active area, the pixel openings correspond to the isolation openings on a one-to-one basis in the active area, and an orthographic projection of the isolation opening on the substrate is located within an orthographic projection of the pixel defining layer on the substrate in the transition area.

13. The display panel according to claim 1, further comprising a touch structure, wherein an orthographic projection of the positioning area on the substrate is located within an orthographic projection of the transition area on the substrate, the touch structure is located on the side of the isolation structure away from the substrate, and an orthographic projection of part of the touch structure on the substrate is located within the transition area.

14. The display panel according to claim 13, wherein the touch structure comprises a touch electrode structure and a touch trace, an orthographic projection of the touch electrode structure on the substrate being located within the active area, and an orthographic projection of at least part of the touch trace on the substrate being located within the transition area.

15. The display panel according to claim 14, wherein
the touch electrode structure comprises a plurality of first touch electrodes arranged in parallel and a plurality of second touch electrodes arranged in parallel, the first touch electrode and the second touch electrode intersecting each other,
wherein the touch trace comprises a first touch signal line connected to the first touch electrode, and a second touch signal line connected to the second touch electrode; and
the first touch electrode comprises a plurality of first touch electrode blocks spaced apart from each other and a plurality of first connecting portions, the first touch electrode blocks of the first touch electrode being connected to each other via the first connecting portions, and the second touch electrode comprises a plurality of second touch electrode blocks spaced apart from each other and a plurality of second connecting portions, the second touch electrode blocks of the second touch electrode being connected to each other via the second connecting portions, and the first connecting portion and the second connecting portion intersecting each other.

16. A preparation method for a display panel, the preparation method comprising:
providing a substrate, which defines an active area and a non-active area surrounding the active area, the non-active area comprising a transition area surrounding and adjacent to the active area, the transition area comprising a positioning area;
forming a plurality of first electrodes on the substrate, wherein the first electrodes are formed in the active area and the transition area;
forming an isolation structure having a plurality of isolation openings on the substrate, wherein the isolation structure is formed in the active area and the transition area, and the isolation openings respectively correspond to the first electrodes; and
forming a plurality of light-emitting functional layers, a plurality of second electrodes and at least one filling structure on the substrate, the light-emitting functional layer and the second electrode being formed in the isolation opening, the first electrode, the light-emitting functional layer and the second electrode stacked in the isolation opening forming a light-emitting device, and the filling structure being formed in the positioning area and on a side of the isolation structure away from the substrate.

17. The preparation method according to claim 16, wherein forming a plurality of light-emitting functional layers, a plurality of second electrodes, and at least one filling structure on the substrate comprises:
depositing a light-emitting functional material and an electrode material after the isolation structure is formed, to respectively form a light-emitting functional structure layer and a second electrode structure layer;
depositing a first insulating material film layer to form a first encapsulation structure layer;
forming a photoresist layer on the first encapsulation structure layer and patterning the photoresist layer to form a photoresist pattern, the photoresist pattern covering part of the isolation openings in the active area and covering the positioning area;
etching the first encapsulation structure layer, the second electrode structure layer and the light-emitting functional structure layer based on the photoresist pattern, and removing parts of the first encapsulation structure layer, the second electrode structure layer and the light-emitting functional structure layer that are not covered by the photoresist pattern, the remaining parts of the first encapsulation structure layer, the second electrode structure layer and the light-emitting functional structure layer respectively forming encapsulation units, second electrodes and light-emitting functional layers, and the first electrode, the light-emitting functional layer and the second electrode stacked in each of the isolation openings forming a light-emitting device, wherein in the positioning area, parts of the first encapsulation structure layer, the second electrode structure layer and the light-emitting functional structure layer that cover the isolation structure are configured to form the filling structure;
removing the rest of the photoresist pattern; and
repeating the above steps to form the light-emitting functional layers, the second electrodes, and the encapsulation units at the remaining isolation openings in the active area, and using the light-emitting functional layers, the second electrodes and the first encapsulation structure layer formed repeatedly in at least part of the isolation openings in the positioning area to form the filling structure, wherein the light-emitting functional layers formed in different processes have different emission colors, and all the encapsulation units form a first encapsulation layer.

18. The preparation method according to claim 16, further comprising:
depositing a pixel defining material film layer on the substrate after forming the first electrodes and before forming the isolation structure; and
patterning the pixel defining material film layer after the isolation structure is formed, to form a plurality of pixel openings in the pixel defining material film layer, wherein at least part of the isolation openings respectively correspond to the pixel openings, and the pixel opening and the isolation opening corresponding to each other are in communicate with each other.

19. A display device comprising a display panel, the display panel having an active area and a non-active area surrounding the active area, the non-active area comprising a transition area surrounding and adjacent to the active area, the transition area comprising a positioning area, and the display panel further comprising:
a substrate;
a plurality of light-emitting devices located in the active area and the transition area;
an isolation structure located on the substrate and comprising a plurality of isolation openings, the isolation structure being located in the active area and the transition area, and the isolation openings respectively corresponding to the light-emitting devices and limiting the corresponding light-emitting devices; and
at least one filling structure located in the positioning area and on a side of the isolation structure away from the substrate.

20. The display device according to claim 19, further comprising a cover plate located on the side of the isolation structure away from the substrate and covering the active area and the non-active area of the display panel.
